(19) United States
(12) Patent Application Publication
(10) Pub. No.: US 2026/0364713 A1
(43) Pub. Date: Nov. 19, 2026

(54) AUTOMATIC REPAIR SYSTEM FOR FAST AND ACCURATE REPAIR OF FINE STRUCTURES

(71) Applicant: Orbotech Ltd., Yavne (IL)

(72) Inventors: Mikhael Matusovsky, Rishon Lezion (IL); Avihay Ankry, Rehovot (IL); Itay Peled, Jerusalem (IL); Dmitri Burshtyn, Yavne (IL); Pini Deri, Yavne (IL)

(21) Appl. No.: 19/208,744

(22) Filed: May 15, 2025

(51) Int. Cl. B23K 26/06

(52) U.S. Cl. CPC B23K 26/06

(57) ABSTRACT

The system includes a processor configured to receive an image of a workpiece from a camera, determine an area of a defect on a surface of the workpiece, determine a plurality of laser positions that together fill the area of the defect, and determine a sequence of laser movements that is discontinuous, such that each laser position is spatially offset from a preceding laser position in the sequence of laser movements. The processor is further configured to generate a sequence of first acoustic signals and a sequence of second acoustic signals for each laser position, send instructions to a laser source to emit the laser beam, and transmit the sequence of first acoustic signals to a first AOD and the sequence of second acoustic signals to a second AOD to direct the laser beam to each of the plurality of laser positions, thereby repairing the defect.

### FIELD OF THE DISCLOSURE

This disclosure relates to semiconductor fabrication and inspection and, more particularly, to laser processing of a printed circuit board.

### BACKGROUND OF THE DISCLOSURE

The evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a workpiece, such as a semiconductor wafer, using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etch, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the wafers, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

A typical repair system includes a laser source synced to a mechanical scanner (e.g., fast steering mirror or pair of galvo mirrors) to scan a laser beam over a desired location to repair a defect. Such a system scans the defect in a raster mode with some defined beam overlaps. However, time is wasted on accelerations due to the inertia of the mechanical scanner compared to the time spent on the defect. In addition, raster-based ablation has limited efficiency due to inducing a high concentration of heat in a local area where each consecutive laser pulse “sees” a target as a mix of debris and partially treated material, which in general results in more debris and recast, and locations of high penetration to the substrate. Furthermore, as defect size reduces to the order of magnitude of the laser spot-size, “rastering” the defect polygon becomes much more complicated and requires fine adjustments of overlap and pulse-energies that will induce asymmetry in the process that will result in bad geometry (e.g., different side wall angle (SWA) on both sides of the defect, higher penetration in the middle of the space or towards the edges, etc.).

Therefore, what is needed is an improved defect repair process.

### BRIEF SUMMARY OF THE DISCLOSURE

An embodiment of the present disclosure provides a system. The system may comprise a stage configured to support a workpiece. The system may further comprise a light source configured to emit light to illuminate a surface of the workpiece. The system may further comprise a camera configured to capture an image of the workpiece based on and the light reflected by the workpiece. The system may further comprise a laser source configured to emit a laser beam onto the surface of the workpiece. The system may further comprise a pair of acousto-optical deflectors (AODs) disposed in a path of the laser beam between the laser source and the workpiece. The pair of AODs may comprise a first AOD configured to deflect the path of the laser beam along an x-axis relative to the surface of the workpiece and a second AOD configured to deflect the path of the laser beam along a y-axis relative to the surface of the workpiece. The system may further comprise a processor in electronic communication with the camera, the laser source, and the pair of AODs. The processor may be configured to receive the image of the workpiece from the camera. The processor may be further configured to determine an area of a defect on the surface of the workpiece based on the image of the workpiece. The processor may be further configured to determine a plurality of laser positions that together fill the area of the defect based on a beam shape of the laser beam at each laser position. The processor may be further configured to determine a sequence of laser movements to direct the laser beam to the plurality of laser positions. The sequence of laser movements may be discontinuous, such that each laser position in the sequence of laser movements may be spatially offset from a preceding laser position. The processor may be further configured to generate a sequence of first acoustic signals defining deflections of the path of the laser beam along the x-axis and a sequence of second acoustic signals defining deflections of the path of the laser beam along the y-axis for each laser position in the sequence of laser movements. The processor may be further configured to send instructions to the laser source to emit the laser beam. The processor may be further configured to transmit the sequence of first acoustic signals to the first AOD and the sequence of second acoustic signals to the second AOD to deflect the path of the laser beam along the x-axis and the y-axis to direct the laser beam to each of the plurality of laser positions according to the sequence of laser movements, thereby repairing the defect.

In some embodiments, the laser source may be configured to emit the laser beam according to a pulse frequency having a time period between pulses. Each laser movement of the sequence of laser movements may be configured to direct the laser beam to a subsequent laser position within the time period between pulses, such that each pulse of the laser beam may be directed to a different one of the plurality of laser positions.

In some embodiments, the processor may be further configured to determine the beam shape of the laser beam based on a shape of the defect.

In some embodiments, the processor may be further configured to determine a pulse energy of the laser beam at each laser position based on a relation between each laser position and the area of the defect.

In some embodiments, the relation between each laser position and the area of the defect may include whether each laser position is an edge position or a bulk position. The pulse energy of the laser beam at each edge position may be less than the pulse energy of the laser beam at each bulk position.

In some embodiments, the processor may be further configured to determine a plurality of sub-areas within the area of the defect. The sequence of laser movements may be determined based on the plurality of laser positions that together fill each of the plurality of sub-areas.

In some embodiments, the first AOD may be further configured to deflect the laser beam along the x-axis based on the sequence of first acoustic signals to define the beam shape relative to the x-axis. The second AOD may be further configured to deflect the laser beam along the y-axis based on the sequence of second acoustic signals to define the beam shape relative to the y-axis.

In some embodiments, the workpiece may be a printed circuit board (PCB). The defect may be a short between a metal pad and a metal line of the PCB.

In some embodiments, the area of the defect may be larger than the beam shape of the laser beam.

In some embodiments, each laser position in the sequence of laser movements may be spatially offset from the preceding laser position by a distance defined by at least one beam waist of the laser beam, such that the laser beam may not overlap with a portion of the workpiece heated by the laser beam at the preceding laser position.

Another embodiment of the present disclosure provides a method. The method may comprise emitting, with a light source, light to illuminate a surface of a workpiece. The method may further comprise capturing, with a camera, an image of the workpiece based on the light reflected by the workpiece. The method may further comprise determining, with a processor, an area of a defect on the surface of the workpiece based on the image of the workpiece received from the camera. The method may further comprise determining, with the processor, a plurality of laser positions that together fill the area of the defect based on a beam shape of a laser beam at each laser position. The method may further comprise determining, with the processor, a sequence of laser movements to direct the laser beam to the plurality of laser positions. The sequence of laser movements may be discontinuous, such that each laser position in the sequence of laser movements may be spatially offset from a preceding laser position. The method may further comprise generating, with the processor, a sequence of first acoustic signals defining deflections of a path of the laser beam along an x-axis relative to the surface of the workpiece and a sequence of second acoustic signals defining deflections of the path of the laser beam along a y-axis relative to the surface of the workpiece for each laser position in the sequence of laser movements. The method may further comprise emitting, with a laser source, the laser beam directed to the surface of the workpiece. The method may further comprise transmitting, with the processor, the sequence of first acoustic signals to a first acousto-optical deflector (AOD) disposed in the path of the laser beam and the sequence of second acoustic signals to a second AOD disposed in the path of the laser beam to deflect the path of the laser beam along the x-axis and the y-axis to direct the laser beam to each of the plurality of laser positions according to the sequence of laser movements, thereby repairing the defect.

In some embodiments, emitting, with the laser source, the laser beam directed to the surface of the workpiece may comprise emitting the laser beam according to a pulse frequency having a time period between pulses. Each laser movement of the sequence of laser movements may be configured to direct the laser beam to a subsequent laser position within the time period between pulses, such that each pulse of the laser beam may be directed to a different one of the plurality of laser positions.

In some embodiments, the method may further comprise determining, with the processor, the beam shape of the laser beam based on a shape of the defect.

In some embodiments, the method may further comprise determining, with the processor, a pulse energy of the laser beam at each laser position based on a relation between each laser position and the area of the defect.

In some embodiments, the relation between each laser position and the area of the defect may include whether each laser position is an edge position or a bulk position. The pulse energy of the laser beam at each edge position may be less than the pulse energy of the laser beam at each bulk position.

In some embodiments, the method may further comprise determining, with the processor, a plurality of sub-areas within the area of the defect. Determining, with the processor, the sequence of laser movements to direct the laser beam to the plurality of laser positions may comprise determining the sequence of laser movements based on the plurality of laser positions that together fill each of the plurality of sub-areas.

In some embodiments, generating, with the processor, the sequence of first acoustic signals and the sequence of second acoustic signals may comprise generating the sequence of first acoustic signals defining the beam shape relative to the x-axis and deflections of the path of the laser beam along the x-axis relative to the surface of the workpiece and generating the sequence of second acoustic signals defining the beam shape relative to the y-axis and deflections of the path of the laser beam along the y-axis relative to the surface of the workpiece.

In some embodiments, the workpiece may be a printed circuit board (PCB). The defect may be a short between a metal pad and a metal line of the PCB.

In some embodiments, the area of the defect may be larger than the beam shape of the laser beam.

In some embodiments, each laser position in the sequence of laser movements may be spatially offset from the preceding laser position by a distance defined by at least one beam waist of the laser beam impacting the surface of the workpiece, such that the laser beam may not overlap with a portion of the workpiece heated by the laser beam at the preceding laser position.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of a system according to an embodiment of the present disclosure;

FIG. 2 is a diagram of an exemplary image of a workpiece captured by the system of FIG. 1;

FIGS. 3A to 3B illustrate exemplary movements of a laser beam within the image of the workpiece of FIG. 2;

FIG. 4A illustrates an exemplary area of a defect of a workpiece having sub-areas defined by edge and bulk areas;

FIG. 4B illustrates an exemplary area of a defect of a workpiece having sub-areas defined by smaller areas;

FIGS. 5A to 5D illustrate exemplary beam shapes of a laser beam;

FIG. 6 is a flowchart of a method according to an embodiment of the present disclosure;

FIG. 7 is a flowchart of a method according to another embodiment of the present disclosure;

FIG. 8 is a flowchart of a method according to another embodiment of the present disclosure;

FIG. 9 is a flowchart of a method according to another embodiment of the present disclosure;

FIG. 10 is a flowchart of a method according to another embodiment of the present disclosure; and

FIG. 11 is a flowchart of a method according to another embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

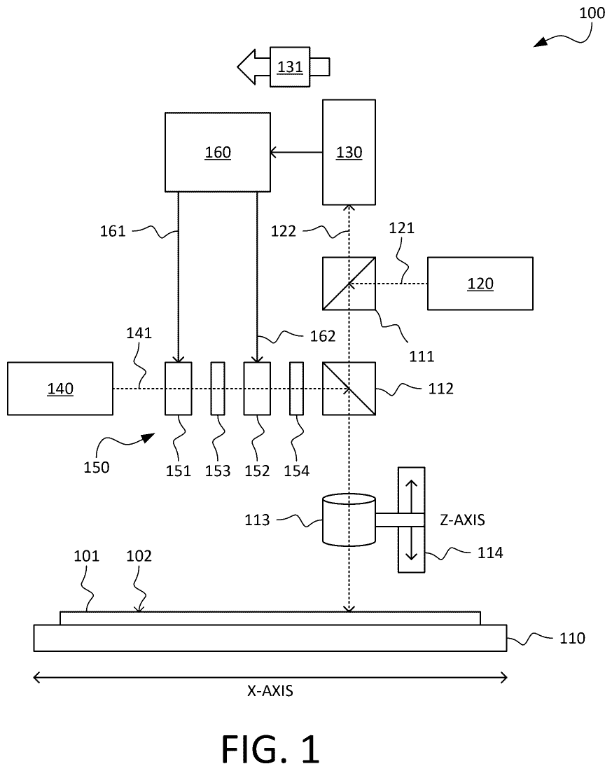

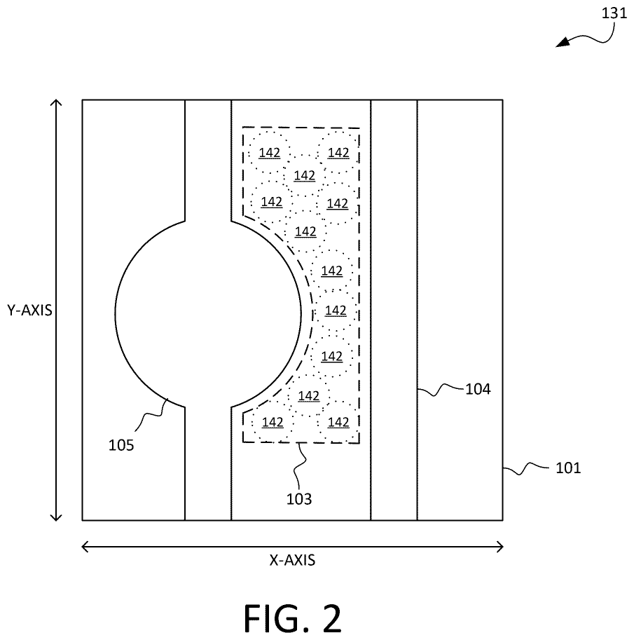

An embodiment of the present disclosure provides a system 100, as shown in FIG. 1. The system 100 may be configured to perform inspection and repair processes on a workpiece 101. The workpiece 101 may be, for example, a semiconductor wafer, substrate, chip, printed circuit board (PCB), flat panel display (FPD), integrated circuit (IC), or other type of workpiece. The workpiece 101 may include one or more defects that can be repaired by laser ablation in an area 103 of a defect. For example, as shown in FIG. 2, the workpiece 101 may be a PCB including one or more metal lines 104, and/or metal pads 105 for connection to electrical components, and the area 103 of the defect may correspond to a short between the metal lines 104 and/or the metal pads 105, and ablation of the area 103 of the defect may correct the short and improve the connection to electrical components.

The system 100 may comprise a stage 110. The stage 110 may be configured to support the workpiece 101. The stage 110 may comprise one or more motors or actuators configured to move the workpiece 101 in one or more in-plane directions (i.e., along the x-axis and/or along the y-axis, as shown in FIG. 2) and/or out-of-plan directions (e.g., along the z-axis, as shown in FIG. 1). The stage 110 may be further configured to hold the workpiece 101 using mechanical clamps, vacuum force, electrostatic force, or other methods.

The system 100 may further comprise a light source 120. The light source 120 may be configured to emit light 121 to illuminate a surface 102 of the workpiece 101. The light source may comprise multiple colors spanning a broad wavelength range. Specifically, the light source 120 may emit light 121 within the wavelength range of approximately 400 nm to 700 nm, encompassing the visible spectrum.

The system 100 may further comprise an optical element (e.g., first beam splitter 111) disposed in the path of the light 121 configured to direct the light 121 onto the surface 102 of the workpiece 101. The light 121 may be directed normal to the surface 102 of the workpiece 101, such that reflected light 122 from the surface 102 of the workpiece 101 along the same optical axis.

In some embodiments, the system 100 may further comprise an objective lens 113 disposed in the path of the light 121 emitted by the light source 120. The objective lens 113 may be configured to focus the light 121 onto the surface 102 of the workpiece 101 based on the position of the objective lens 113 along the z-axis. The system 100 may further comprise an objective stage 114 including one or more motors or actuators configured to move the objective lens 113 along the z-axis to adjust the focus of the light 121 onto the surface 102 of the workpiece 101.

The system 100 may further comprise a camera 130. The camera 130 may be configured to capture an image 131 of the workpiece 101 based on the light 122 reflected by the workpiece 101. For example, the reflected light 122 from the surface 102 of the workpiece 101 may be directed normal to the surface 102 of the workpiece 101, through the first beam splitter 111 to the camera 130. In an instance, example parameters of the camera 130 may include a resolution of 2048 ×2048 pixels, a pixel size of 5.5×5.5 μm, and a frame rate of up to 90 frames per second. Additionally, the camera 130 may utilize a progressive scan CMOS sensor with a global shutter. The camera 130 may also support synchronization via hardware or software triggers and offer exposure time control programmable through the camera API. The image 131 of the workpiece 101 may include a portion of the workpiece 101 within a field of view of the camera 130, as shown in FIG. 2.

The system 100 may further comprise a laser source 140. The laser source 140 may be configured to emit a laser beam 141 onto the surface 102 of the workpiece 101. In an instance, the laser source 140 may be configured to emit a laser beam 141 in the form of a 532 nm pulse laser with a pulse energy above 5 mJ and a repetition rate above 20 kHz. The system 100 may further comprise an optical element (e.g., second beam splitter 112) disposed on the path of the laser beam 141 configured to direct the laser beam 141 onto the surface 102 of the workpiece 101. Directing the laser beam 141 onto the surface 102 of the workpiece 101 may focus high energy onto a concentrated area of the workpiece 101 for ablation and repair of fine structures. In some embodiments, the laser source 140 may be configured to emit the laser beam 141 according to a pulse frequency. Accordingly, each pulse of the laser beam 141 may be configured to impact the surface 102 of the workpiece 101.

The system 100 may further comprise a pair of acousto-optical deflectors (AODs) 150 disposed in the path of the laser beam 141 between the laser source 140 and the workpiece 101. The pair of AODs 150 may be configured to deflect the path of the laser beam 141 in response to receiving acoustic signals. The pair of AODs 150 may comprise a first AOD 151 and a second AOD 152. The first AOD 151 may be configured to deflect the path of the laser beam 141 along the x-axis relative to the surface 102 of the workpiece 101, and the second AOD 152 may be configured to deflect the path of the laser beam 141 along the y-axis relative to the surface 102 of the workpiece 101. Accordingly, the pair of AODs 150 may be configured to control the x-y location where the laser beam 141 impacts the surface 102 of the workpiece 101. In some embodiments, the first AOD 151 may be further configured to define a beam shape of the laser beam 141 relative to the x-axis, and the second AOD 152 may be further configured to define a beam shape of the laser beam 141 relative to the y-axis. Accordingly, the pair of AODs 150 may be further configured to control the beam shape of the laser beam 141 that impacts the surface 102 of the workpiece 101. The system 100 may further comprise a first relay lens 153 disposed between the first AOD 151 and the second AOD 152, and a second relay lens 154 disposed between the second AOD 152 and the second beam splitter 112. The first relay lens 153 may be configured to direct the laser beam 141 deflected by the first AOD 151 to the second AOD 152, and the second relay lens 154 may be configured to direct the laser beam deflected by the second AOD 152 to the second beam splitter 112 to the exit pupil of the objective lens 113. The first relay lens 153 and the second relay lens 154 may each include one or more lenses or other optical elements and is not limited herein.

The system 100 may further comprise one or more additional optical elements disposed in the path(s) of the light 121 from the light source 120, the reflected light 122 from the surface 102 of the workpiece 101, and/or the laser beam 141 from the laser source 140, such as, for example, beam splitters, mirrors, lenses, beam expanders, polarizers, filters (e.g., spectral or chromatic filters), or other elements.

The system 100 may further comprise a processor 160. The processor 160 may include a microprocessor, a microcontroller, or other devices. The processor 160 may be coupled to the components of the system 100 in any suitable manner (e.g., via one or more transmission media, which may include wired and/or wireless transmission media) such that the processor 160 can receive output. The processor 160 may be configured to perform a number of functions using the output. An inspection tool can receive instructions or other information from the processor 160. The processor 160 optionally may be in electronic communication with another inspection tool, a metrology tool, a repair tool, or a review tool (not illustrated) to receive additional information or send instructions.

The processor 160 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 160 may be disposed in or otherwise part of the system 100 or another device. In an example, the processor 160 may be part of a standalone control unit or in a centralized quality control unit. Multiple processors 160 may be used, defining multiple subsystems of the system 100.

The processor 160 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 160 to implement various methods and functions may be stored in readable storage media, such as a memory.

If the system 100 includes more than one subsystem, then the different processors 160 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 160 may be configured to perform a number of functions using the output of the system 100 or other output. For instance, the processor 160 may be configured to send the output to an electronic data storage unit or another storage medium. The processor 160 may be further configured as described herein.

The processor 160 may be configured according to any of the embodiments described herein. The processor 160 also may be configured to perform other functions or additional steps using the output of the system 100 or using images or data from other sources.

The processor 160 may be communicatively coupled to any of the various components or sub-systems of system 100 in any manner known in the art. Moreover, the processor 160 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 160 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single processor 160 (or computer subsystem) or, alternatively, multiple processors 160 (or multiple computer subsystems). Moreover, different sub-systems of the system 100 may include one or more computing or logic systems. Therefore, the above description should not be interpreted as a limitation on the present disclosure but merely an illustration.

The processor 160 may be in electronic communication with the stage 110. For example, the processor 160 may be configured to send instructions to the one or more motors or actuators of the stage 110 to move the workpiece 101 relative to the light 121 and the laser beam 141 (e.g., along the x-axis and/or along the y-axis) to adjust where the light 121 and the laser beam 141 impacts the surface 102 of the workpiece 101.

The processor 160 may be in electronic communication with the light source 120. For example, the processor 160 may be configured to send instructions to the light source 120 to emit the light 121 to illuminate the surface 102 of the workpiece 101.

The processor 160 may be in electronic communication with the camera 130. For example, the processor 160 may be configured to receive the image 131 of the workpiece 101 captured by the camera 130. The processor 160 may be further configured to determine an area 103 of a defect on the surface 102 of the workpiece 101 based on the image 131 of the workpiece 101. For example, the processor 160 may use an image processing algorithm to identify features and structures on the surface 102 of the workpiece 101 (e.g., a metal line 104 and/or a metal pad 105) and determine whether areas between these structures contain an area 103 of a defect that can be repaired by laser ablation (e.g., a short). As shown in FIG. 2, the image 131 of the workpiece 101 may include an area 103 of a defect between a metal line 104 and a metal pad 105. Although the area 103 is shown between a metal line 104 and a metal pad 105, the area 103 may similarly correspond to a defect between two metal lines 104 or two metal pads 105. The shape of the area 103 may vary depending on the adjacent structures, and may be, for example, any polygonal, circular, annular, or irregular-shaped area on the surface 102 of the workpiece 101. While the area 103 of the defect is described in connection with the adjacent structures on the surface 102 of the workpiece, the area 103 of the defect may correspond to any portion of the surface 102 of the workpiece 101 that can be repaired by laser ablation.

The processor 160 may be further configured to determine a plurality of laser positions 142 that together fill the area 103 of the defect based on the beam shape of the laser beam 141 at each laser position 142. For example, as shown in FIG. 2, based on a known or preset beam shape of the laser beam 141, the processor 160 may determine the x-y location of each laser position 142 that fill the area 103 of the defect. The area 103 of the defect may be larger than the beam shape of the laser beam 141, such that the laser beam 141 may impact the surface 102 of the workpiece 101 at each of the plurality of laser positions 142 to fill the area 103 of the defect for repair.

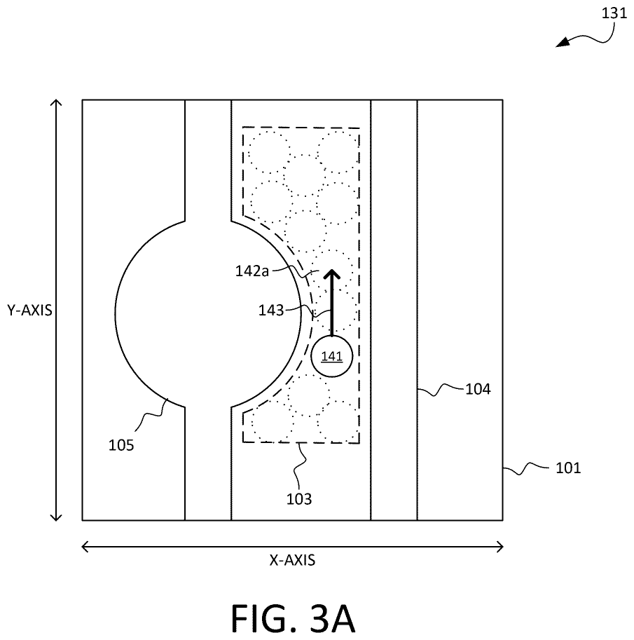

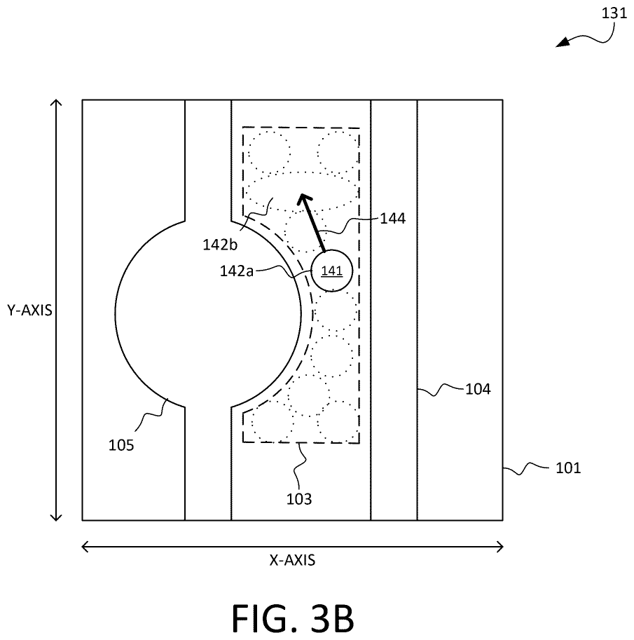

The processor 160 may be further configured to determine a sequence of laser movements to direct the laser beam 141 to the plurality of laser positions 142. The sequence of laser movements may be discontinuous, such that each laser position of the plurality of laser positions 142 is spatially offset from a preceding laser position. For example, as shown in FIG. 3A, a first step 143 in the sequence of laser movements may move the laser beam 141 to a laser position 142a that is not immediately adjacent to the preceding laser position. In this way, the step 143 may move the laser beam 141 to a position 142a away from the preceding laser position to avoid overheating of the workpiece 101 in overlapping areas where the laser beam 141 impacts the surface 102 of the workpiece 101. Each laser position in the sequence of laser movements may be spatially offset from the preceding laser position by a distance defined by at least one beam waist of the laser beam 141, such that the laser beam 141 does not overheat part of the workpiece 101 that was also impacted at the preceding laser position. The beam waist may be defined by the Gaussian distribution of the intensity of the laser beam 141, where the relative intensity is at least 1/e² of the maximum value. Separation by a distance greater than one beam waist of the laser beam 141 may further reduce overlap and possible overheating of the workpiece 101. Each subsequent step in the sequence of laser movements may follow this pattern, eventually returning to fill the positions between earlier steps once the workpiece 101 has sufficiently cooled, so as to not overheat the workpiece 101 when filling the area 103 of the defect.

The processor 160 may be further configured to generate a sequence of first acoustic signals 161 and a sequence of second acoustic signals 162 based on the sequence of laser movements to direct the laser beam 141 to the plurality of laser positions 142. The sequence of first acoustic signals 161 may define the deflections of the path of the laser beam 141 along the x-axis for each laser position of the sequence of laser movements, and the sequence of second acoustic signals 162 may define the deflections of the path of the laser beam long the y-axis for each laser position of the sequence of laser movements. Accordingly, the sequence of first acoustic signals 161 and the sequence of second acoustic signals 162 may together define the sequence of movements of the laser beam 141 to each x-y position of the plurality of laser positions 142.

The processor 160 may be in electronic communication with the laser source 140. For example, the processor 160 may be configured to send instructions to the laser source 140 to emit the laser beam 141 to be directed onto the surface 102 of the workpiece 101. In some embodiments, the instructions may include the pulse frequency to define the time period of each pulse of the laser beam 141.

The processor 160 may be in electronic communication with the pair of AODs 150. For example, the processor 160 may transmit the sequence of first acoustic signals 161 to the first AOD 151, and the processor 160 may transmit the sequence of second acoustic signals 162 to the second AOD 152. Accordingly, the first AOD 151 and the second AOD 152 may deflect the path of the laser beam 141 along the x-axis and the y-axis to direct the laser beam 141 to each of the plurality of laser positions according to the sequence of laser movements, thereby repairing the defect. In some embodiments, the camera 130 may continuously capture images 131 of the workpiece 101 throughout the repair process to track the location of the area 103 of the defect and as the laser beam 141 is directed to each of the plurality of laser positions and to verify that the area 103 of the defect has been repaired following the sequence of laser movements.

In some embodiments, the sequence of first acoustic signals 161 and the sequence of second acoustic signals 162 may be defined such that each laser movement of the sequence of laser movements is configured to direct the laser beam to the subsequent laser position within the time period between pulses. For example, the first AOD 151 and the second AOD 152 may be configured to deflect the path of the laser beam 141 along the x-axis and the y-axis to any position within the range in a time of about 10 microseconds, while a typical galvo scanner may take 200 microseconds or more to move to different positions (depending on the distance traveled). Accordingly, each pulse of the laser beam 141 may be directed to a different one of the plurality of laser positions 142 for efficient processing of the workpiece 101 for defect repair.

In some embodiments, the processor 160 may be further configured to define the beam shape of the laser beam 141 so as to optimize or minimize the plurality of laser positions 142 that together fill the area 103 of the defect. For example, the processor 160 may be further configured to determine the beam shape of the laser beam 141 based on a shape of the defect. In other words, the processor 160 may generate the sequence of first acoustic signals 161 and the sequence of second acoustic signals 162 to deflect the laser beam 141 along the x-axis and/or along the y-axis to align with a shape or contour of the area 103 of the defect at each of the plurality of laser positions. Therefore, the first AOD 151 may be further configured to deflect the laser beam 141 along the x-axis based on the sequence of first acoustic signals 161 to define the beam shape relative to the x-axis, and the second AOD 152 may be further configured to deflect the laser beam 141 along the y-axis based on the sequence of second acoustic signals 162 to define the beam shape relative to the y-axis. Accordingly, the laser beam 141 may more efficiently fill the area 103 of the defect while minimizing impacts with areas outside of the area 103 of the defect.

In some embodiments, the processor 160 may be further configured to determine a pulse energy of the laser beam 141 at each laser position 142 based on a relation between each laser position and the area of the defect. For example, the relation between each laser position 142 may include whether each laser position is an edge position (adjacent to an edge of the area of the defect) or a bulk position (within the area of the defect). The processor 160 may be configured to send instructions to the laser source 140 to emit the laser beam 141 such that laser pulses directed to the edge positions have a lower pulse energy compared to laser pulses directed to the bulk positions. This may mitigate differences in ablation rates due to different heat flow between edge positions and bulk positions in the area 103 of the defect and can minimize overheating.

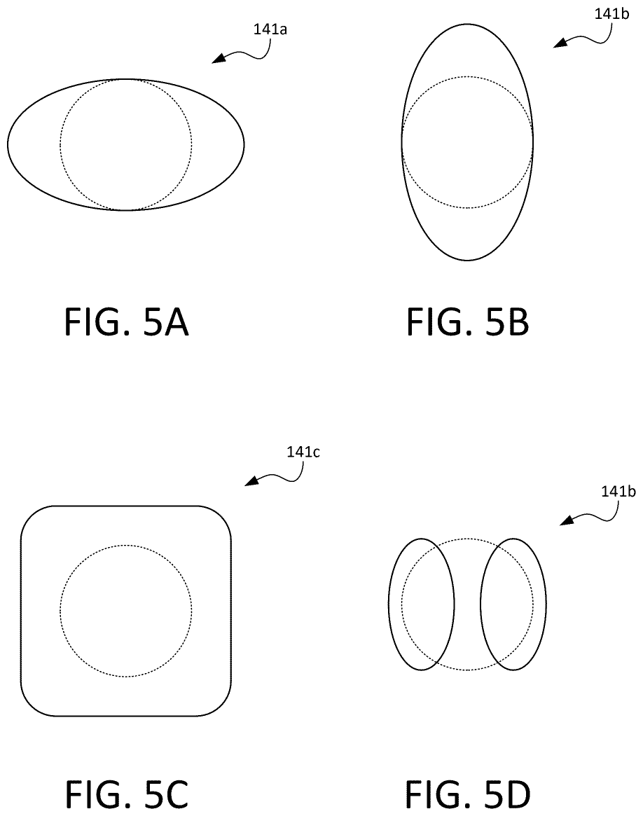

FIG. 5A-D illustrate exemplary beam shapes of the laser beam 141, which may be selected by the processor 160 for each of the plurality of laser positions 142 of the sequence of laser movements, and the processor 160 may generate the sequence of first acoustic signals 161 and the sequence of second acoustic signals 162 to deflect the laser beam 141 relative to the x-axis and/or the y-axis to achieve the determined beam shape in each laser position. For example, FIG. 5A illustrates a beam shape 141a having a deflection forming an ellipse that is wider along the x-axis compared to the original shape, FIG. 5B illustrates a beam shape 141b having a deflection forming an ellipse that is wider along the y-axis compared to the original shape, FIG. 5C illustrates a beam shape 141c having deflections forming a shape that is wider along the x-axis and the y-axis compared to the original shape. The degree of deflections along the x-axis and the y-axis may vary, and are not limited to the exemplary beam shapes illustrated herein. Different beam shapes can be achieved using chirped acoustic (RF) signals or several superimposed multifrequency signals having different amplitudes and phases, which, when applied to the first AOD 151, expand the laser beam 141 along the x-axis, and when applied to the second AOD 152, expand the laser beam 141 along the y-axis. Expanding the laser beam 141 along both the x-axis and the y-axis may eventually produce a laser beam 141 having a substantially rectangular shape. In addition, multi-frequency signals can produce more complex shapes, for example, where lines or rows of a matrix can be toggled to produce larger shapes or discontinuous shapes (e.g., the beam shape 141d shown in FIG. 5D) that may be smaller than the diffraction limit (i.e., the original beam shape). Using these beam shapes, the laser beam 141 can align with the contour of the area 103 of the defect in each of the plurality of laser positions 142 to more efficiently fill the area 103 of the defect while minimizing impacts with areas outside of the area 103 of the defect and minimizing overlaps with a preceding laser position. For example, as shown in FIG. 3B, a second step 144 in the sequence of laser movemements may move the laser beam 141 to a laser position 142b that is separated from the preceding laser position 142a, and also changes the beam shape to align with the contour of the area 103 of the defect by widening the shape of the laser beam 141 along the x-axis, such that the area 103 of the defect can be repaired in single passes to minimize the number of laser positions and overall repair time.

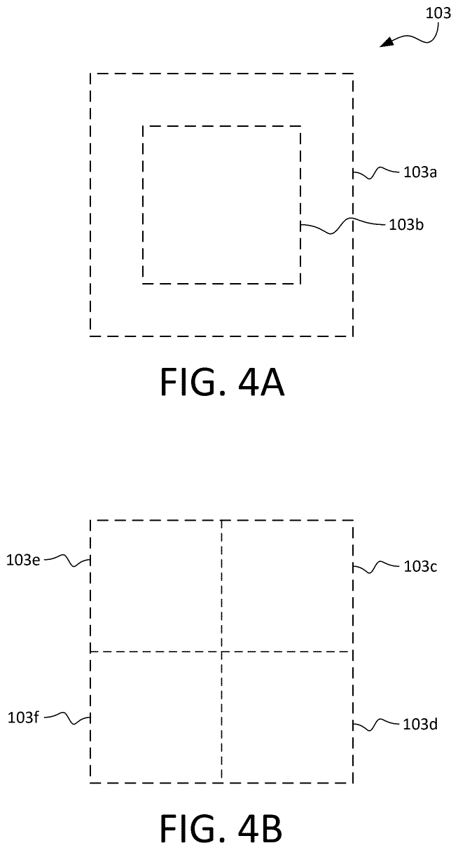

In some embodiments, the processor 160 may be further configured to determine a plurality of sub-areas within the area 103 of the defect. For example, as shown in FIG. 4A, the area 103 of the defect may be divided into two sub-areas 103a and 103b that correspond to edge areas and bulk areas of the area 103 of the defect. In another example, as shown in FIG. 4B, the area 103 of the defect may be divided into four sub-area 103c, 103d, 103e, and 103f that correspond to smaller grid areas of the area 103 of the defect. The plurality of sub-areas may have different shapes and is not limited by the exemplary sub-areas illustrated herein. For example, each sub-area may be defined to align with the contour of a structure within the area 103 of the defect, a particular area of having the same beam shape of the laser beam 141 for repair, or other areas having similar features or repair parameters. The processor 160 may be configured to determine the sequence of laser movements based on the plurality of laser positions 142 that together fill each of the plurality of sub-areas. For example, the sequence of laser movements may be defined such that the laser beam 141 moves to each of the laser positions 142 within one of the sub-areas first (in a discontinuous manner), then the laser beam 141 moves to the laser positions 142 of the other sub-areas to separately repair each sub-area before moving to the next sub-area, which may minimize the number of changes of the beam shape through the sequence of laser movements.

With the system 100, the repair process of the area 103 of the defect on the surface 102 of the workpiece 101 may have higher throughput and accuracy due to the ability to construct a sequence of laser movements for deflections with the pair of AODs 150 with a complex scanning order instead of raster trajectories. This improves process efficiency along with the minimization of debris and recast, and allows minimization of damage level to workpiece 101 outside of the area 103 of the defect. In addition, dynamic beam shaping with the pair of AODs 150 can allow the laser beam 141 to follow any defect shape or induce sweeping effects in a desired direction (e.g., inward, outward, interleaved, etc.) for better geometry reconstruction.

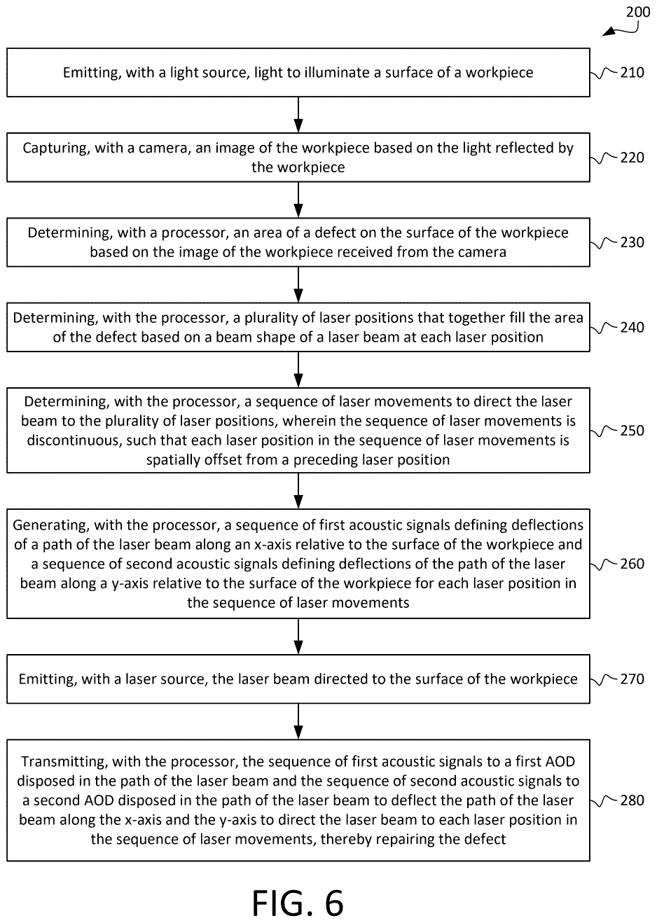

Another embodiment of the present disclosure provides a method 200. As shown in FIG. 6, the method 200 may comprise the following steps.

At step 210, a light source emits light to illuminate a surface of a workpiece.

At step 220, a camera captures an image of the workpiece based on the light reflected by the workpiece.

At step 230, a processor determines an area of a defect on the surface of the workpiece based on the image of the workpiece received from the camera.

At step 240, the processor determines a plurality of laser positions that together fill the area of the defect based on a beam shape of a laser beam at each laser position.

At step 250, the processor determines a sequence of laser movements to direct the laser beam to the plurality of laser positions. The sequence of laser movements may be discontinuous, such that each laser position in the sequence of laser movements is spatially offset from a preceding laser position.

At step 260, the processor determines a sequence of first acoustic signals defining deflections of a path of the laser beam along an x-axis relative to the surface of the workpiece and a sequence of second acoustic signals defining deflections of the path of the laser beam along a y-axis relative to the surface of the workpiece for each laser position in the sequence of laser movements.

At step 270, a laser source emits the laser beam directed to the surface of the workpiece.

At step 280, the processor transmits the sequence of first acoustic signals to a first acousto-optical deflector (AOD) disposed in the path of the laser beam and the sequence of second acoustic signals to a second AOD disposed in the path of the laser beam to deflect the path of the laser beam along the x-axis and the y-axis to direct the laser beam to each laser position in the sequence of laser movements, thereby repairing the defect.

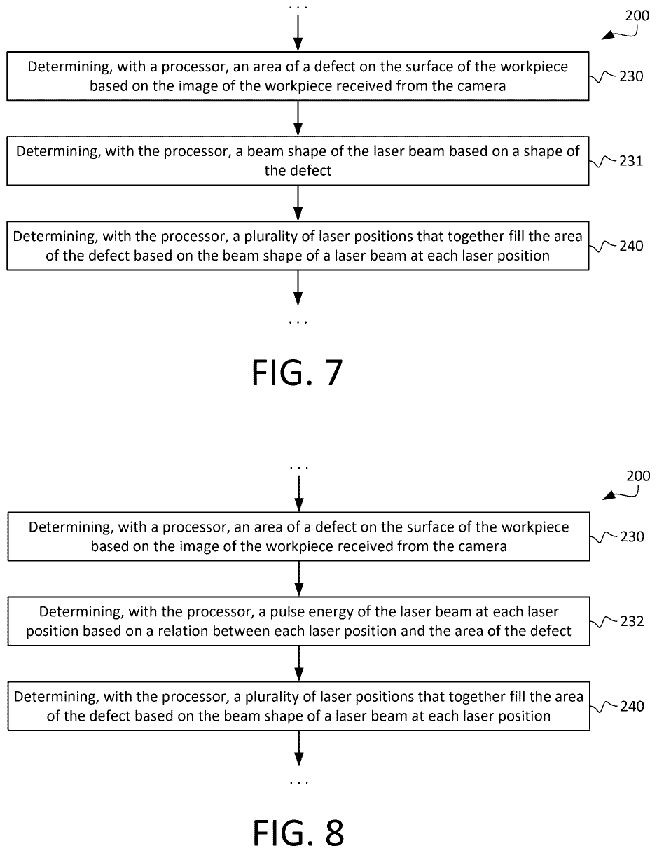

In some embodiments, the method 200 may further comprise step 231, as shown in FIG. 7. At step 231, the processor determines a beam shape of the laser beam based on a shape of the defect. For example, the beam shape of the laser beam may be widened relative to the x-axis and/or the y-axis to fill wider areas of the defect in a single pass. Step 231 may be performed after step 230, for example, between step 230 and step 240.

In some embodiments, the method 200 may further comprise step 232, as shown in FIG. 8. At step 232, the processor determines a pulse energy of the laser beam at each laser position based on a relation between each laser position and the area of the defect. For example, the relation between each laser position and the area of the defect includes whether each laser position is an edge position or a bulk position. The pulse energy of the laser beam may be reduced at the edge positions compared to the bulk positions, which may mitigate differences in ablation rates due to different heat flow between edge positions and bulk positions in the area of the defect and can minimize overheating. Step 232 may be performed after step 230, for example, between step 230 and step 240.

In some embodiments, the method 200 may comprise both step 231 and step 232. In other words, the processor may determine the beam shape of the laser beam at each laser position based on the overall shape of the defect and the pulse energy of the laser beam at each laser position based on the relation between each laser position and the area of the defect. Accordingly, each laser position may have a beam shape and pulse energy to optimize the repair process.

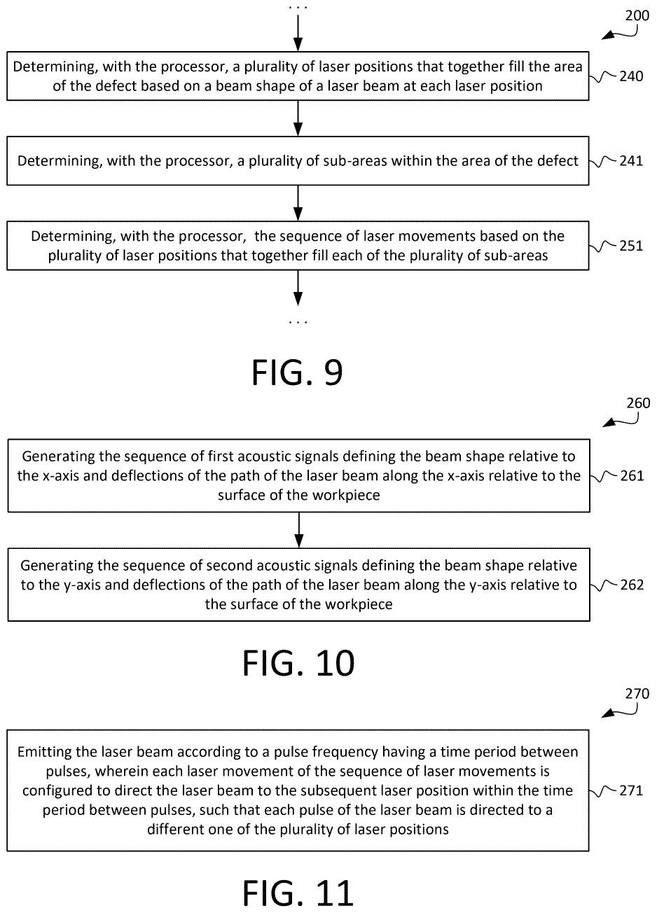

In some embodiments, the method 200 may further comprise step 241, as shown in FIG. 9. At step 241, the processor determines a plurality of sub-areas within the area of the defect. In other words, the area of the defect may be divided into a plurality of sub-areas, which may divide the plurality of laser positions between those that fill each of the plurality of sub-areas. The sub-areas may be determined based on the area of the defect (e.g., a large area may be divided into smaller areas of preset size), the shape of the defect (e.g., the area may be divided into discrete preset shapes), and/or the relation with the area of the defect (e.g., one sub-area may include edge positions and another sub-area may include bulk positions). Step 241 may be performed after step 240, for example, between step 240 and step 250. In this embodiment, step 250 may comprise step 251. At step 251, the processor determines the sequence of laser movements based on the plurality of laser positions that together fille each of the plurality of sub-areas. For example, the sequence of laser movements may be configured to move to the plurality of laser positions of one sub-area first, before moving to a different sub-area to selectively repair the defect in an area-by-area sequence.

In some embodiments, step 260 may comprise step 261 and step 262, as shown in FIG. 10. At step 261, the processor generates the sequence of first acoustic signals defining the beam shape relative to the x-axis and deflections of the path of the laser beam along the x-axis relative to the surface of the workpiece. At step 262, the processor generates the sequence of second acoustic signals defining the beam shape relative to the y-axis and deflections of the path of the laser beam along the y-axis relative to the surface of the workpiece. Accordingly, the sequence of first acoustic signals and the sequence of second acoustic signals may define the beam shape at each of the plurality of laser positions to further fine tune the laser processing sequence for repairing the defect.

In some embodiments, step 270 may comprise step 271, as shown in FIG. 11. At 271, the laser source emits the laser beam according to a pulse frequency having a time period between pulses. Each laser movement of the sequence of laser movements may be configured to direct the laser beam to the subsequent laser position within the time period between pulses, such that each pulse of the laser beam is directed to a different one of the plurality of laser positions. Accordingly, the pair of AODs can direct the laser beam between the plurality of laser positions quickly between each laser pulse to efficiently repair the defect.

With the method 200, the repair process of the area of the defect on the surface of the workpiece may have higher throughput and accuracy due to the ability to construct a sequence of laser movements for AOD deflections with a complex scanning order instead of raster trajectories. This improves process efficiency along with the minimization of debris and recast, and allows minimization of damage level to workpiece outside of the area of the defect. In addition, dynamic beam shaping using AODs can allow the laser beam to follow any defect shape or induce sweeping effects in a desired direction (e.g., inward, outward, interleaved, etc.) for better geometry reconstruction.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a stage configured to support a workpiece;
a light source configured to emit light to illuminate a surface of the workpiece;
a camera configured to capture an image of the workpiece based on and the light reflected by the workpiece;
a laser source configured to emit a laser beam onto the surface of the workpiece;
a pair of acousto-optical deflectors (AODs) disposed in a path of the laser beam between the laser source and the workpiece, wherein the pair of AODs comprises:
a first AOD configured to deflect the path of the laser beam along an x-axis relative to the surface of the workpiece; and
a second AOD configured to deflect the path of the laser beam along a y-axis relative to the surface of the workpiece; and
a processor in electronic communication with the camera, the laser source, and the pair of AODs, wherein the processor is configured to:
receive the image of the workpiece from the camera;
determine an area of a defect on the surface of the workpiece based on the image of the workpiece;
determine a plurality of laser positions that together fill the area of the defect based on a beam shape of the laser beam at each laser position;
determine a sequence of laser movements to direct the laser beam to the plurality of laser positions, wherein the sequence of laser movements is discontinuous, such that each laser position in the sequence of laser movements is spatially offset from a preceding laser position;
generate a sequence of first acoustic signals defining deflections of the path of the laser beam along the x-axis and a sequence of second acoustic signals defining deflections of the path of the laser beam along the y-axis for each laser position in the sequence of laser movements;
send instructions to the laser source to emit the laser beam; and
transmit the sequence of first acoustic signals to the first AOD and the sequence of second acoustic signals to the second AOD to deflect the path of the laser beam along the x-axis and the y-axis to direct the laser beam to each of the plurality of laser positions according to the sequence of laser movements, thereby repairing the defect.

2. The system of claim 1, wherein the laser source is configured to emit the laser beam according to a pulse frequency having a time period between pulses, and each laser movement of the sequence of laser movements is configured to direct the laser beam to a subsequent laser position within the time period between pulses, such that each pulse of the laser beam is directed to a different one of the plurality of laser positions.

3. The system of claim 1, wherein the processor is further configured to determine the beam shape of the laser beam based on a shape of the defect.

4. The system of claim 1, wherein the processor is further configured to determine a pulse energy of the laser beam at each laser position based on a relation between each laser position and the area of the defect.

5. The system of claim 4, wherein the relation between each laser position and the area of the defect includes whether each laser position is an edge position or a bulk position, and the pulse energy of the laser beam at each edge position is less than the pulse energy of the laser beam at each bulk position.

6. The system of claim 1, wherein the processor is further configured to determine a plurality of sub-areas within the area of the defect, and the sequence of laser movements is determined based on the plurality of laser positions that together fill each of the plurality of sub-areas.

7. The system of claim 1, wherein the first AOD is further configured to deflect the laser beam along the x-axis based on the sequence of first acoustic signals to define the beam shape relative to the x-axis, and the second AOD is further configured to deflect the laser beam along the y-axis based on the sequence of second acoustic signals to define the beam shape relative to the y-axis.

8. The system of claim 1, wherein the workpiece is a printed circuit board (PCB), and the defect is a short between a metal pad and a metal line of the PCB.

9. The system of claim 1, wherein the area of the defect is larger than the beam shape of the laser beam.

10. The system of claim 1, wherein each laser position in the sequence of laser movements is spatially offset from the preceding laser position by a distance defined by at least one beam waist of the laser beam, such that the laser beam does not overlap with a portion of the workpiece heated by the laser beam at the preceding laser position.

11. A method comprising:
emitting, with a light source, light to illuminate a surface of a workpiece;
capturing, with a camera, an image of the workpiece based on the light reflected by the workpiece;
determining, with a processor, an area of a defect on the surface of the workpiece based on the image of the workpiece received from the camera;
determining, with the processor, a plurality of laser positions that together fill the area of the defect based on a beam shape of a laser beam at each laser position;
determining, with the processor, a sequence of laser movements to direct the laser beam to the plurality of laser positions, wherein the sequence of laser movements is discontinuous, such that each laser position in the sequence of laser movements is spatially offset from a preceding laser position;
generating, with the processor, a sequence of first acoustic signals defining deflections of a path of the laser beam along an x-axis relative to the surface of the workpiece and a sequence of second acoustic signals defining deflections of the path of the laser beam along a y-axis relative to the surface of the workpiece for each laser position in the sequence of laser movements;
emitting, with a laser source, the laser beam directed to the surface of the workpiece; and
transmitting, with the processor, the sequence of first acoustic signals to a first acousto-optical deflector (AOD) disposed in the path of the laser beam and the sequence of second acoustic signals to a second AOD disposed in the path of the laser beam to deflect the path of the laser beam along the x-axis and the y-axis to direct the laser beam to each of the plurality of laser positions according to the sequence of laser movements, thereby repairing the defect.

12. The method of claim 11, wherein emitting, with the laser source, the laser beam directed to the surface of the workpiece comprises:
emitting the laser beam according to a pulse frequency having a time period between pulses, wherein each laser movement of the sequence of laser movements is configured to direct the laser beam to a subsequent laser position within the time period between pulses, such that each pulse of the laser beam is directed to a different one of the plurality of laser positions.

13. The method of claim 11, further comprising:
determining, with the processor, the beam shape of the laser beam based on a shape of the defect.

14. The method of claim 11, further comprising:
determining, with the processor, a pulse energy of the laser beam at each laser position based on a relation between each laser position and the area of the defect.

15. The method of claim 14, wherein the relation between each laser position and the area of the defect includes whether each laser position is an edge position or a bulk position, and the pulse energy of the laser beam at each edge position is less than the pulse energy of the laser beam at each bulk position.

16. The method of claim 11, further comprising:
determining, with the processor, a plurality of sub-areas within the area of the defect;
wherein determining, with the processor, the sequence of laser movements to direct the laser beam to the plurality of laser positions comprises:
determining the sequence of laser movements based on the plurality of laser positions that together fill each of the plurality of sub-areas.

17. The method of claim 11, wherein generating, with the processor, the sequence of first acoustic signals and the sequence of second acoustic signals comprises:
generating the sequence of first acoustic signals defining the beam shape relative to the x-axis and deflections of the path of the laser beam along the x-axis relative to the surface of the workpiece; and
generating the sequence of second acoustic signals defining the beam shape relative to the y-axis and deflections of the path of the laser beam along the y-axis relative to the surface of the workpiece.

18. The method of claim 11, wherein the workpiece is a printed circuit board (PCB), and the defect is a short between a metal pad and a metal line of the PCB.

19. The method of claim 11, wherein the area of the defect is larger than the beam shape of the laser beam.

20. The method of claim 11, wherein each laser position in the sequence of laser movements is spatially offset from the preceding laser position by a distance defined by at least one beam waist of the laser beam impacting the surface of the workpiece, such that the laser beam does not overlap with a portion of the workpiece heated by the laser beam at the preceding laser position.
